(19) United States
(12) Patent Application Publication
(10) Pub. No.: US 2025/0309184 A1
(43) Pub. Date: Oct. 2, 2025

(54) APPARATUS AND METHOD FOR OPERATING ELECTRONIC COMPONENTS

(71) Applicant: ALL RING TECH CO., LTD., Kaohsiung City (TW)

(72) Inventors: Kai-Min CHANG, Kaohsiung City (TW); Yu-Xian ZHUANG, Kaohsiung City (TW)

(21) Appl. No.: 19/060,305

(22) Filed: Feb. 21, 2025

(30) Foreign Application Priority Data
Mar. 27, 2024 (TW) 113111562

(51) Int. Cl. H01L 23/00; H01L 21/66

(52) U.S. Cl. CPC H01L 24/75; H01L 22/12; H01L 24/83; H01L 2224/75901; H01L 2224/83908

(57) ABSTRACT

An apparatus for operating electronic components includes a transporting unit including an operating rail for transporting a workpiece, and an operating unit including an operating mechanism movably disposed above the operating rail. The operating mechanism has an operating head disposed to implement a predetermined operating process to the workpiece, and an electrostatic measuring device for measuring an electrostatic charge of the workpiece to minimize the risk of damaging the workpiece by electrostatic discharge.

### CROSS-REFERENCE TO RELATED APPLICATION

This application claims priority to Taiwanese Patent Application No. 113111562, filed on Mar. 27, 2024, and incorporated by reference herein in its entirety.

### FIELD

The disclosure relates to an apparatus and a method for operating electronic components, and more particularly to an apparatus and a method for measuring an electrostatic charge on a workpiece before implementing a predetermined operating process on the workpiece by an operating head.

### BACKGROUND

In a semiconductor manufacturing process, workpieces are required to undergo several processes first before becoming qualified for forming an integrated circuit. For example, as described in TWI1568324, “Method and Apparatus for Attaching Heatsink,” the method includes subjecting a substrate that carries a chip to a series of predetermined processes including adhesive bonding, heatsink attaching, etc.

In the semiconductor manufacturing process, static electricity is accumulated on the workpieces, and electrostatic discharge (ESD) may occur when the workpieces undergo the predetermined processes, thereby damaging the integrated circuit.

### SUMMARY

Therefore, an object of the disclosure is to provide an apparatus and a method for operating electronic components that can alleviate at least one of the drawbacks of the prior art.

According to an aspect of the disclosure, the apparatus for operating electronic components includes a transporting unit including an operating rail for transporting a workpiece along a transporting path, and an operating unit including an operating mechanism disposed above the operating rail and movable relative to the operating rail. The operating mechanism has an operating head which is disposed to implement a predetermined operating process on the workpiece, and an electrostatic measuring device for measuring an electrostatic charge of the workpiece.

According to another aspect of the disclosure, the method for operating electronic components by using the apparatus described previously, includes transporting a workpiece on the operating rail to an operating area; measuring an electrostatic charge of the workpiece in the operating area by the electrostatic measuring device; and, if the electrostatic charge of the workpiece is smaller than a predetermined value, implementing the predetermined operating process on the workpiece by an operating head; and, if the electrostatic charge on the workpiece is not smaller than the predetermined value, the operating head does not implement the predetermined operating process on the workpiece.

### BRIEF DESCRIPTION OF THE DRAWINGS

Other features and advantages of the disclosure will become apparent in the following detailed description of the embodiments with reference to the accompanying drawings. It is noted that various features may not be drawn to scale.

FIG. 1 is a perspective view of a workpiece.

FIG. 2 is a perspective view illustrating an embodiment of an apparatus for operating the workpiece according to the disclosure.

FIG. 3 is a schematic top view illustrating a transporting unit of the apparatus.

FIG. 4 is a schematic top view illustrating an operating unit of the apparatus.

FIG. 5 is an exploded perspective view illustrating an operating mechanism of the operating unit.

FIG. 6 is a perspective view illustrating an operating unit of another embodiment of the apparatus.

FIG. 7 is an exploded perspective view illustrating an operating mechanism of the operating unit in FIG. 6.

FIG. 8 is a perspective view illustrating an operating unit of still another embodiment of the apparatus.

FIG. 9 is an exploded perspective view illustrating an operating mechanism of the operating unit in FIG. 8.

### DETAILED DESCRIPTION

Before the disclosure is described in greater detail, it should be noted that where considered appropriate, reference numerals or terminal portions of reference numerals have been repeated among the figures to indicate corresponding or analogous elements, which may optionally have similar characteristics.

It should be noted herein that for clarity of description, spatially relative terms such as “top,” “bottom,” “upper,” “lower,” “on,” “above,” “over,” “downwardly,” “upwardly” and the like may be used throughout the disclosure while making reference to the features as illustrated in the drawings. The features may be oriented differently (e.g., rotated 90 degrees or at other orientations) and the spatially relative terms used herein may be interpreted accordingly.

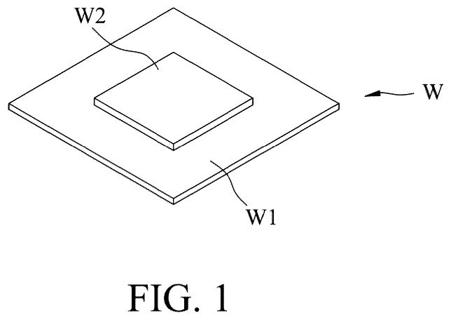

Referring to FIG. 1, an embodiment of an apparatus 1 for operating workpieces according to the disclosure is adapted to implement a predetermined operating process on a workpiece (W) that includes a substrate (W1) and a chip (W2) on the substrate (W1). For example, the predetermined operating process may be one of an adhesive bonding process that involves applying an adhesive to the substrate (W1), a thermal interface material attaching process that involves attaching a thermal interface material to the chip (W2), and a heatsink attaching process that involves attaching a heatsink to the workpiece (W).

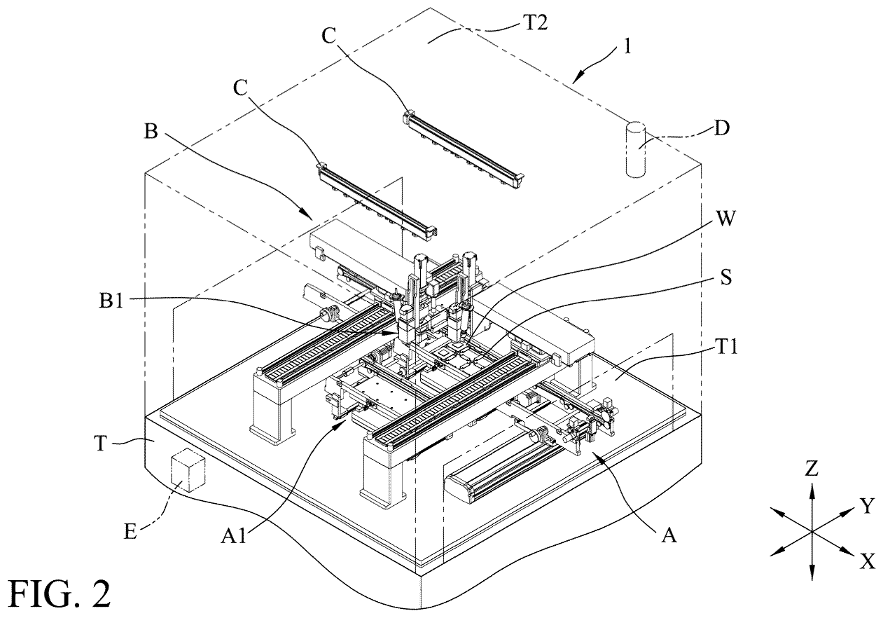

With reference to FIG. 2, the operating apparatus 1 is mounted on a worktable (T1) of a machine base (T), and includes a transporting unit (A) and an operating unit (B). The transporting unit (A) includes an operating rail (A11) for transporting the workpiece (W) along a transporting path. The operating unit (B) includes an operating mechanism (B1) disposed above the operating rail (A11) and movable relative to the operating rail (A11).

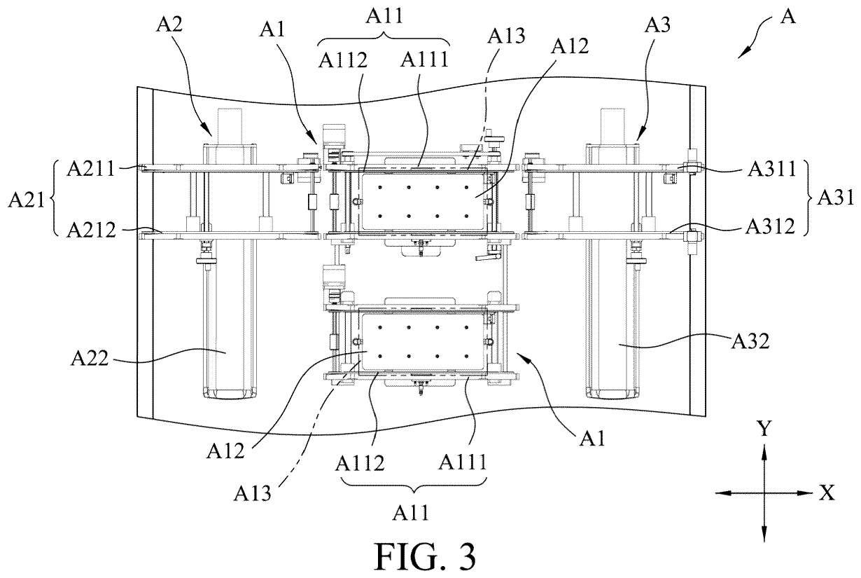

With reference to FIGS. 2 and 3, specifically, the transporting unit (A) includes two of the operating rail mechanisms (A1) which are disposed parallel to each other in an X-axis direction and aligned with each other in a Y-axis direction, an upstream rail mechanism (A2) and a downstream rail mechanism (A3) which are respectively disposed at two ends of the two operating rail mechanisms (A1).

The operating rail mechanism (A1) includes the operating rail (A11) for conveying the workpiece (W), and a platform (A12) which is movable relative to the operating rail (A11) in a Z-axis direction. The operating rail (A11) has two rail strips (A111) and two conveyor belts (A112) disposed inwardly of the rail strips (A111). The platform (A12) is disposed between the two rail strips (A111). A plurality of the workpieces (W) are carried on a tray carrier(S) in a matrix arrangement. The tray carrier(S) is transported horizontally through the conveyor belts (A112) to an operating area (A13) corresponding with the platform (A12).

The upstream rail mechanism (A2) includes an upstream rail (A21) on an upstream rail driving seat (A22) extending in the Y-axis direction. The upstream rail (A21) has two rail strips (A211) and two conveyor belts (A212) disposed inwardly of the rail strips (A211). The tray carrier(S) on which the workpieces (W) are carried is transported horizontally through the conveyor belts (A212) along the transporting path. The upstream rail driving seat (A22) drives movement of the upstream rail (A21) to selectively align and engage the upstream rail (A21) with an upstream end of one of the operating rail mechanisms (A1).

The downstream rail mechanism (A3) includes a downstream rail (A31) on a downstream rail driving seat (A32) extending in the Y-axis direction. The downstream rail (A31) has two rail strips (A311) and two conveyor belts (A312) disposed inwardly of the rail strips (A311). The tray carrier(S) on which the workpieces (W) are carried is transported horizontally through the conveyor belts (A312) along the transporting path. The downstream rail driving seat (A32) drives movement of the downstream rail (A31) to selectively align and engage the downstream rail (A31) with a downstream end of one of the operating rail mechanisms (A1).

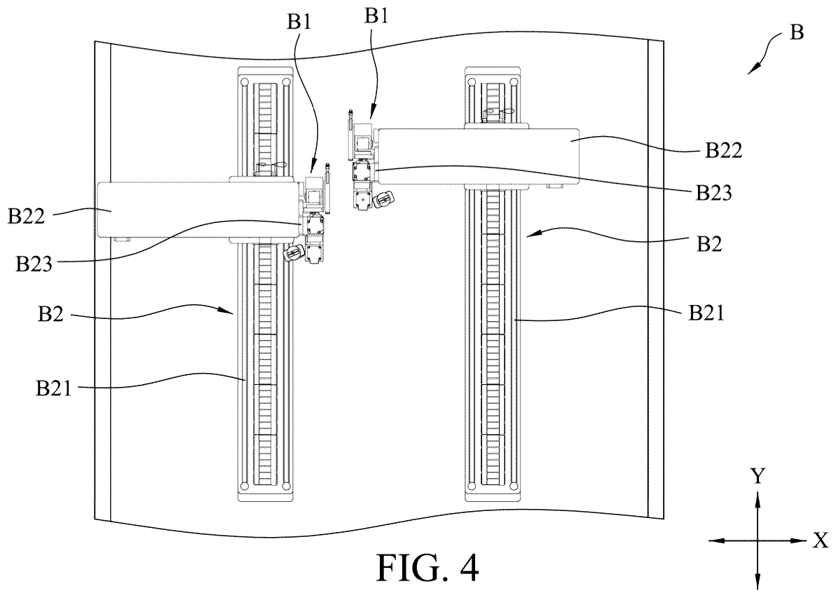

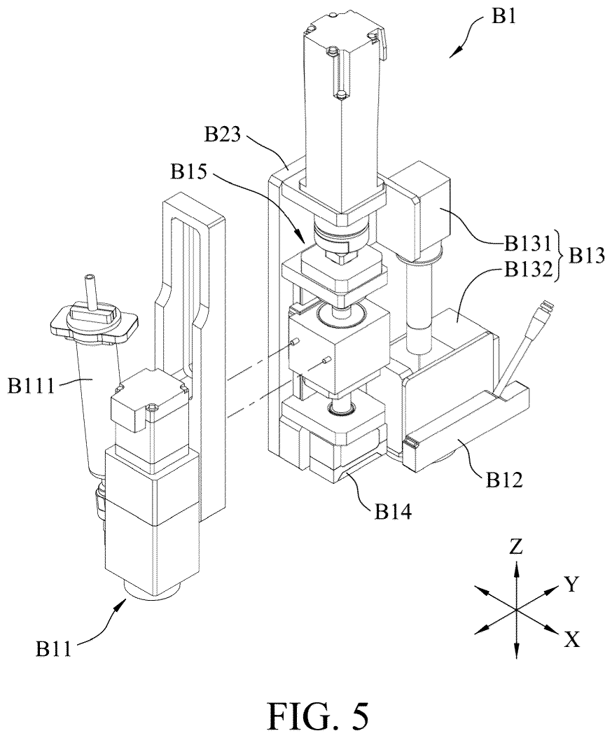

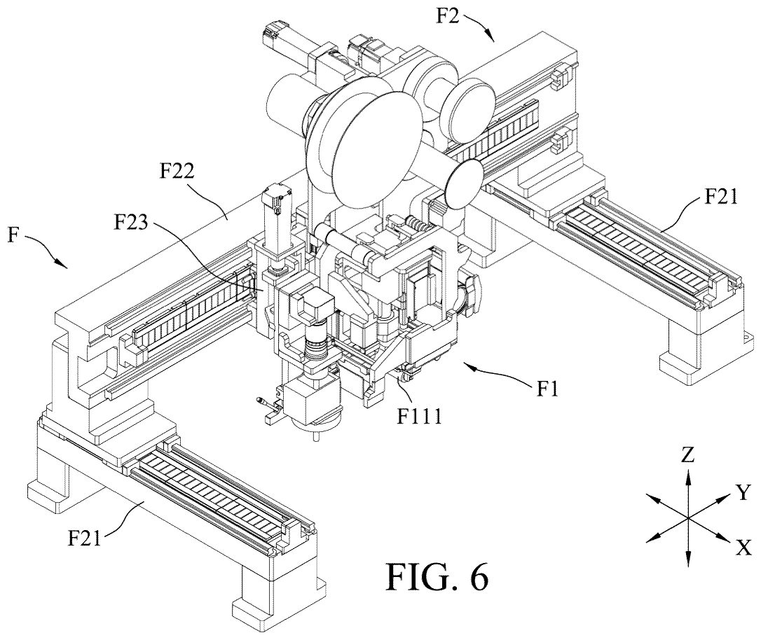

With reference to FIG. 2 and FIGS. 4 to 6, the operating unit (B) includes two of the operating mechanisms (B1), and two driving mechanisms (B2) disposed parallel to each other in the Y-axis direction and aligned with each other in the X-axis direction to respectively drive multi-axis movements of the two operating mechanisms (B1) relative to the operating rail mechanisms (A1).

The operating mechanism (B1) has an operating head (B11) which is disposed to implement the adhesive bonding process on the workpiece (W), an electrostatic measuring device (B12) for measuring an electrostatic charge of the workpiece (W), a visual alignment assembly (B13) for searching a position of the workpiece (W), a distance measuring device (B14) for measuring a distance from the workpiece (W), and a Z-axis driving assembly (B15) for driving movement of the operating head (B11) and the distance measuring device (B14) in the Z-axis direction. The operating head (B11) is in the form of a glue dispensing valve that is provided with a glue reservoir (B111) and that applies an adhesive to the substrate (W1). The glue dispensing valve may be a screw dispensing valve, a piezoelectric dispensing valve, a pneumatic adhesive dispensing valve, etc. Static electricity conduction is generated between the operating head (B11) and the workpiece (W) during the adhesive bonding process.

The driving mechanism (B2) includes a Y-axis driving bracket (B21) extending in the Y-axis direction, an X-axis driving bracket (B22) disposed on the Y-axis driving bracket (B21) and extending in the X-axis direction, and a seat bracket (B23) disposed on the X-axis driving bracket (B22).

The operating mechanism (B1) is disposed on the seat bracket (B23), and is moved with the X-axis driving bracket (B22) in both the X-axis direction and the Y-axis direction relative to the Y-axis driving bracket (B21) such that the operating head (B11), the electrostatic measuring device (B12), the visual alignment assembly (B13), the distance measuring device (B14) and the Z-axis driving assembly (B15) are moved horizontally together with the seat bracket (B23).

Specifically, the electrostatic measuring device (B12) and the visual alignment assembly (B13) are securely mounted on the seat bracket (B23). The visual alignment assembly (B13) includes an image capturing device (B131) and a light source (B132) disposed downwardly of the image capturing device (B131). The electrostatic measuring device (B12) is disposed adjacent to the light source (B132) to measure electrostatic charge downwardly. The operating head (B11) and the distance measuring device (B14) are disposed on the Z-axis driving assembly (B15) so as to be moved in the Z-axis direction relative to the seat bracket (B23). In other words, the electrostatic measuring device (B12) and the visual alignment assembly (B13) are operably and horizontally movable in both the X-axis direction and the Y-axis direction, and the operating head (B11) and the distance measuring device (B14) are operably, horizontally and vertically movable in the X-axis direction, the Y-axis direction and the Z-axis direction.

With reference to FIGS. 2 and 3, a cover (T2) is disposed to cover the transporting unit (A) and the operating unit (B). An electrostatic eliminator (C) is disposed above the transporting path of each operating rail (A11) for eliminating electrostatic charge of the workpiece (W). The electrostatic eliminator (C) is mounted on and inside the cover (T2) and is located above the operating rail (A11), and produces electrically charged gases that are ejected downwardly.

The apparatus 1 further includes a warning alarm device (D) which is disposed outside the cover (T2) to warn an operator with light or sound.

The apparatus 1 further includes a control unit (E) disposed within the machine base (T). The control unit (E) receives the information measured or captured by the electrostatic measuring device (B12), the visual alignment assembly (B13) and the distance measuring device (B14) on the workpiece (W), and controls the transporting unit (A) and the operating unit (B) to implement the predetermined operating process on the workpiece (W), the electrostatic eliminator (C) to eliminate electrostatic charge of the workpiece (W), and/or the warning alarm device (D) to generate a warning alarm.

During the operation of the apparatus 1, the tray carrier(S) on which the workpieces (W) are carried is transported along the transporting path to the operating area (A13), and the platform (A12) is raised to attach and retain the tray carrier(S).

The operating head (B11) is moved horizontally to the operating area (A13), and an electrostatic charge of the workpiece (W) in the operating area (A13) is measured by the electrostatic measuring device (B12) before the operating head (B11) is aligned with the workpiece (W) in the operating area (A13) to perform the predetermined operating process on the workpiece (W).

If the electrostatic charge of the workpiece (W) is determined by the control unit (E) to be smaller than a predetermined value, the operating head (B11) is operated to implement the predetermined operating process on the workpiece (W).

If the electrostatic charge of the workpiece (W) is determined by the control unit E to be no smaller than the predetermined value, the operating head (B11) does not implement the predetermined operating process on the workpiece (W).

In this embodiment, in the step of implementing the predetermined operating process on the workpiece (W) by the operating head (B11), the operating head (B11) performs an adhesive bonding process as the predetermined operating process to apply an adhesive to the substrate (W1) of the workpiece (W). Specifically, before the operating head (B11) is aligned with the workpiece (W) positioned in the operating area

(A13) to perform the predetermined operating process on the workpiece (W), the visual alignment assembly (B13) moved horizontally together with the operating head (B11) is operated to search each workpiece (W) on the tray carrier(S) in the operating area (A13) while the electrostatic measuring device (B12) moved horizontally together with the visual alignment assembly (B13) is operated to measure an electrostatic charge of the workpiece (W).

When the electrostatic charge of the workpiece (W) is measured to be less than the predetermined value, the distance measuring device (B14) moved horizontally together with the operating head (B11) is operated to measure the distance from the workpiece (W), and the Z-axis driving assembly (B15) is actuated to adjust the distance between the operating head (B11) and the workpiece (W) so as to make the operating head (B11) perform the predetermined operating process on the workpiece (W) at a predetermined height.

When the electrostatic charge of the workpiece (W) is measured to be not less than the predetermined value, the electrostatic eliminator (C) is operated to eliminate the electrostatic charge of the workpiece (W), and the electrostatic measuring device (B12) is then operated to measure again an electrostatic charge of the workpiece (W). When the electrostatic charge of the workpiece (W) is still measured to be not less than the predetermined value after the step of eliminating the electrostatic charge of the workpiece (W) by the electrostatic eliminator (C), a warning alarm is produced by the warning alarm device (D) and sent to the operator.

After the step of implementing the predetermined operating process on the workpiece (W) by the operating head (B11), an electrostatic charge of the workpiece (W) is measured by the electrostatic measuring device (B12).

By virtue of the apparatus and method of the disclosure, the operating head (B11) is not operated to perform the predetermined operating process when the electrostatic charge of the workpiece (W) is not less than the predetermined value, which may minimize the risk of damaging the workpiece (W) by electrostatic discharge (ESD).

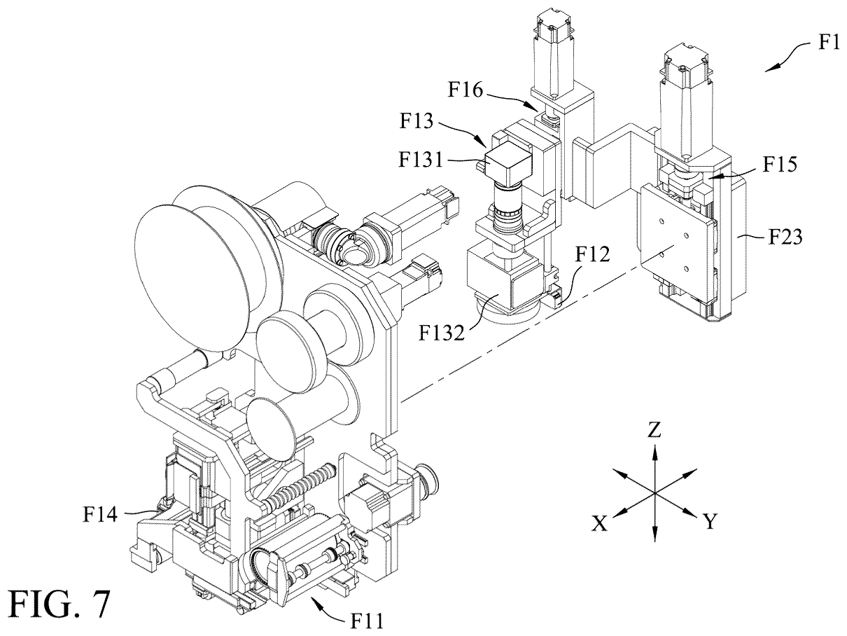

Referring to FIGS. 1, 6 and 7, in another embodiment, the operating head (F11) of the operating mechanism (F1) of the operating unit (F) is disposed to perform a thermal interface material attaching process as the predetermined operating process to attach a thermal interface material to the chip (W2) of the workpiece (W). The operating unit (F) includes an operating mechanism (F1) disposed on and driven by a driving mechanism (F2) to perform a multi-axis movement.

The operating mechanism (F1) includes an operating head (F11) for implementing the thermal interface material attaching process on the workpiece (W), an electrostatic measuring device (F12) for measuring an electrostatic charge of the workpiece (W), a visual alignment assembly (F13) for searching the position of the workpiece (W), a distance measuring device (F14) for measuring the distance from the workpiece (W), a first Z-axis driving assembly (F15) for driving movement of the operating head (F11) and the distance measuring device (F14) in the Z-axis direction, and a second Z-axis driving assembly (F16) for driving movement of the electrostatic measuring device (F12) and the visual alignment assembly (F13) in the Z-axis direction. The operating head (F11) is used with a carrier tape on which the thermal interface material (TIM) is removably disposed, and has a roller (F111) which is disposed to roll over the carrier tape to attach the thermal interface material to the chip (W2). Static electricity conduction is generated between the operating head (F11) and the workpiece (W) during the thermal interface material attaching process. The visual alignment assembly (F13) includes an image capturing device (F131) and a light source (F132) disposed downwardly of the image capturing device (F131). The electrostatic measuring device (F12) is disposed adjacent to the light source (F132) to measure electrostatic charge downwardly.

The driving mechanism (F2) includes two X-axis driving brackets (F21) extending in the X-axis direction, a Y-axis driving bracket (F22) riding on the two X-axis driving brackets (F21) and extending in the Y-axis direction, and a seat bracket (F23) disposed on the Y-axis driving bracket (F22). The Y-axis driving bracket (F22) is movable on the two X-axis driving brackets (F21) in the X-axis direction. The seat bracket (F23) is movable on the Y-axis driving bracket (F22) in the Y-axis direction.

The operating mechanism (F1) is disposed on the (seat bracket (F23), and is moved with the seat bracket (F23) in both the X-axis direction and the Y-axis direction such that the operating head (F11), the electrostatic measuring device (F12), the visual alignment assembly (F13), the distance measuring device (F14), the first Z-axis driving assembly (F15) and the second Z-axis driving assembly (F16) are moved horizontally together with the seat bracket (F23).

Specifically, the operating head (F11) and the distance measuring device (F14) are disposed on the first Z-axis driving assembly (F15) to be moved vertically relative to the seat bracket (F23). The electrostatic measuring device (F12) and the visual alignment assembly (F13) are disposed on the second Z-axis driving assembly (F16) to be moved vertically relative to the seat bracket (F23). In other words, all of the operating head (F11), the electrostatic measuring device (F12), the visual alignment assembly (F13) and the distance measuring device (F14) are operably movable in the X-axis direction, the Y-axis direction and the Z-axis direction. The vertical movement of the operating head (F11) and the distance measuring device (F14) is separate from the vertical movement of the electrostatic measuring device (F12) and the visual alignment assembly (F13).

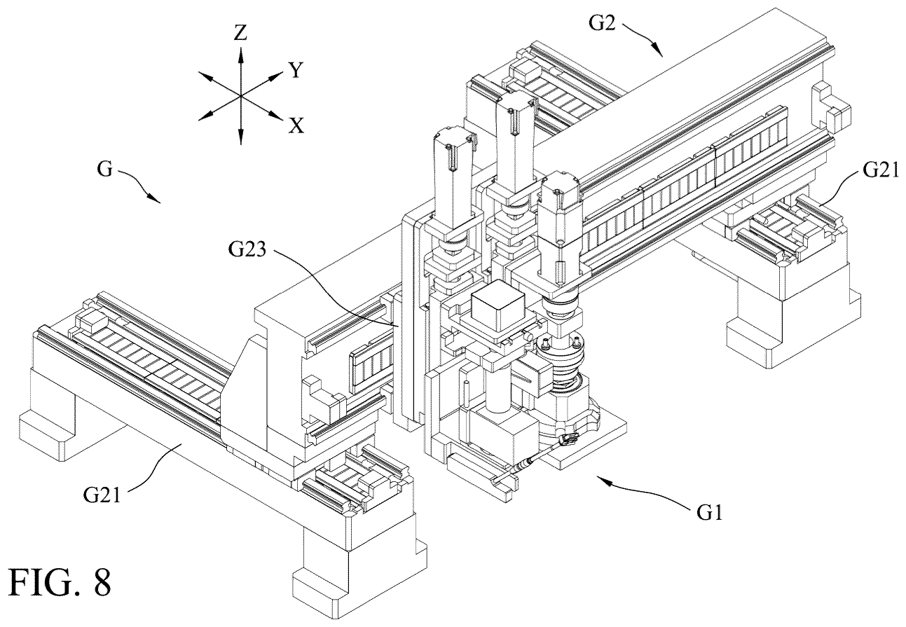

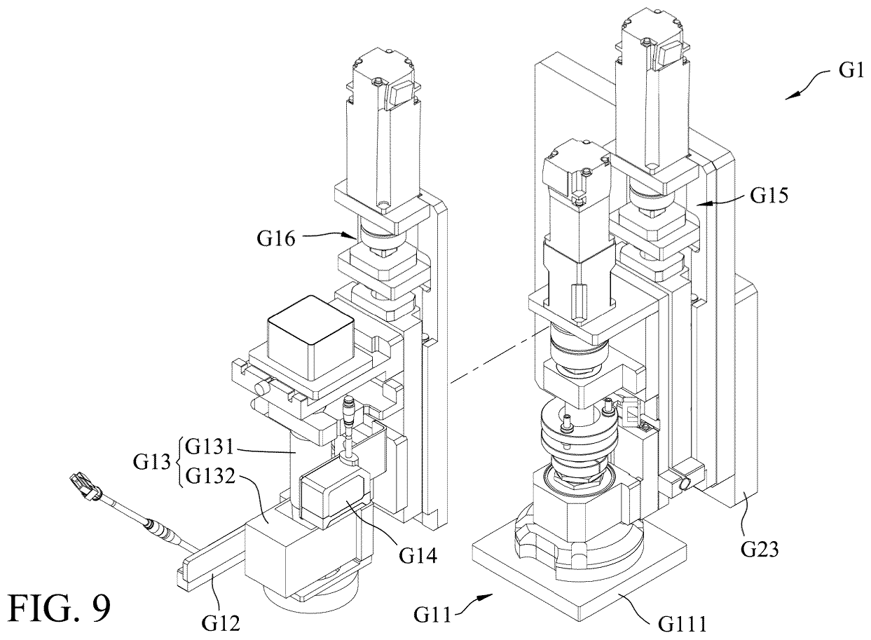

Referring to FIGS. 1, 8 and 9, in still another embodiment, the operating head (G11) of the operating mechanism (G1) of the operating unit (G) is disposed to perform a heatsink attaching process as the predetermined operating process to attach a heatsink to the workpiece (W). The operating unit (G) includes an operating mechanism (G1) disposed on and driven by a driving mechanism (G2) to make a multi-axis movement.

The operating mechanism (G1) includes an operating head (G11) for implementing the heatsink attaching process on the workpiece (W), an electrostatic measuring device (G12) for measuring an electrostatic charge of the workpiece (W), a visual alignment assembly (G13) for searching the position of the workpiece (W), a distance measuring device (G14) for measuring the distance from the workpiece (W), a first Z-axis driving assembly (G15) for driving movement of the operating head (G11) in the Z-axis direction, and a second Z-axis driving assembly (G16) for driving movement of the electrostatic measuring device (G12), the visual alignment assembly (G13) and the distance measuring device (G14) in the Z-axis direction. The operating head (G11) has a suction member (G111) for drawing the heatsink. Static electricity conduction is generated between the operating head (G11) and the workpiece (W) during the heatsink attaching process. The visual alignment assembly (G13) includes an image capturing device (G131) and a light source (G132) disposed downwardly of the image capturing device (G131). The electrostatic measuring device (G12) is disposed adjacent to the light source (G132) to measure electrostatic charge downwardly.

The driving mechanism (G2) includes two X-axis driving brackets (G21) extending in the X-axis direction, a Y-axis driving bracket (G22) riding on the two X-axis driving brackets (G21) and extending in the Y-axis direction, and a seat bracket (G23) disposed on the Y-axis driving bracket (G22). The Y-axis driving bracket (G22) is movable on the two X-axis driving brackets (G21) in the X-axis direction. The seat bracket (G23) is movable on the Y-axis driving bracket (G22) in the Y-axis direction.

The operating mechanism (G1) is disposed on the seat bracket (G23), and is moved with the seat bracket (G23) in both of the X-axis direction and the Y-axis direction such that the operating head (G11), the electrostatic measuring device (G12), the visual alignment assembly (G13), the distance measuring device (G14), the first Z-axis driving assembly (G15) and the second Z-axis driving assembly (G16) are moved horizontally together with the seat bracket (G23).

Specifically, the operating head (G11) is disposed on the first Z-axis driving assembly (G15) to be moved vertically relative to the seat bracket (G23). The electrostatic measuring device (G12), the visual alignment assembly (G13) and the distance measuring device (G14) are disposed on the second Z-axis driving assembly (G16) to be moved vertically relative to the seat bracket (G23). In other words, all of the operating head (G11), the electrostatic measuring device (G12), the visual alignment assembly (G13) and the distance measuring device (G14) are operably movable in the X-axis direction, the Y-axis direction and the Z-axis direction. The vertical movement of the operating head (G11) is separate from the vertical movement of the electrostatic measuring device (F12), the visual alignment assembly (F13) and the distance measuring device (F14).

In the description above, for the purposes of explanation, numerous specific details have been set forth in order to provide a thorough understanding of the embodiments. It will be apparent, however, to one skilled in the art, that one or more other embodiments may be practiced without some of these specific details. It should also be appreciated that reference throughout this specification to “one embodiment,” “an embodiment,” an embodiment with an indication of an ordinal number and so forth means that a particular feature, structure, or characteristic may be included in the practice of the disclosure. It should be further appreciated that in the description, various features are sometimes grouped together in a single embodiment, figure, or description thereof for the purpose of streamlining the disclosure and aiding in the understanding of various inventive aspects; such does not mean that every one of these features needs to be practiced with the presence of all the other features. In other words, in any described embodiment, when implementation of one or more features or specific details does not affect implementation of another one or more features or specific details, said one or more features may be singled out and practiced alone without said another one or more features or specific details. It should be further noted that one or more features or specific details from one embodiment may be practiced together with one or more features or specific details from another embodiment, where appropriate, in the practice of the disclosure.

While the disclosure has been described in connection with what are considered the exemplary embodiments, it is understood that this disclosure is not limited to the disclosed embodiments but is intended to cover various arrangements included within the spirit and scope of the broadest interpretation so as to encompass all such modifications and equivalent arrangements.

What is claimed is:

1. An apparatus for operating a workpiece, comprising:
a transporting unit including an operating rail for transporting the workpiece along a transporting path;
an operating unit including an operating mechanism disposed above said operating rail and movable relative to said operating rail, said operating mechanism having an operating head which is disposed to implement a predetermined operating process on the workpiece, and an electrostatic measuring device for measuring an electrostatic charge of the workpiece.

2. The apparatus of claim 1, wherein said operating mechanism further has a visual alignment assembly which is operably disposed to be moved with said operating head and said electrostatic measuring device.

3. The apparatus of claim 2, wherein said operating unit further includes a seat bracket, each of said operating head, said electrostatic measuring device and said visual alignment assembly being directly or indirectly mounted on said seat bracket so as to be moved together with said seat bracket.

4. The apparatus of claim 1, further comprising an electrostatic eliminator which is disposed above said operating rail for eliminating electrostatic charge over the workpiece.

5. The apparatus of claim 4, further comprising a cover which covers said transporting unit and said operating unit, wherein said electrostatic eliminator is mounted on and inside said cover and located above said operating rail, and produces electrically charged gas that ejects downwardly.

6. The apparatus of claim 1, the workpiece including a substrate and a chip carried on the substrate, wherein said operating head is disposed to perform an adhesive bonding process as the predetermined operating process, where static electricity conduction is generated between said operating head and the workpiece during the adhesive bonding process, said operating head being in form of a glue dispensing valve provided with a glue reservoir to apply an adhesive to the substrate.

7. The apparatus of claim 1, the workpiece including a substrate and a chip carried on the substrate, wherein said operating head is disposed to perform a thermal interface material attaching process as the predetermined operating process, where static electricity conduction is generated between said operating head and the workpiece during the thermal interface material attaching process, said operating head being used with a carrier tape on which the thermal interface material is removably disposed, and having a roller which is disposed to roll over the carrier tape to attach the thermal interface material to the chip.

8. The apparatus of claim 1, wherein said operating head is disposed to perform a heatsink attaching process as the predetermined operating process, where static electricity conduction is generated between said operating head and the workpiece during the heatsink attaching process, said operating head having a suction member for drawing the heatsink.

9. A method for operating a workpiece by using an apparatus as claimed in claim 1, comprising:
transporting a workpiece on the operating rail to an operating area;
measuring an electrostatic charge of the workpiece in the operating area by the electrostatic measuring device; and
if the electrostatic charge of the workpiece is less than a predetermined value, implementing the predetermined operating process on the workpiece by the operating head; and
if the electrostatic charge of the workpiece is not less than the predetermined value, the operating head does not implement the predetermined operating process on the workpiece.

10. The method of claim 9, wherein, before the step of measuring an electrostatic charge of the workpiece in the operating area by the electrostatic measuring device, the operating head is moved to the operating area.

11. The method of claim 9, wherein the electrostatic measuring device is moved together with the operating head.

12. The method of claim 9, wherein, in the step of transporting a workpiece on the operating rail to an operating area, a tray carrier on which a plurality of the workpieces are carried in a matrix arrangement is transported to the operating area, each of the workpieces is searched by a visual alignment assembly, and the electrostatic measuring device is moved together with the visual alignment assembly to measure an electrostatic charge of the workpieces.

13. The method of claim 9, wherein, in the step of implementing the predetermined operating process to the workpiece by the operating head, static electricity conduction is generated between the operating head and the workpiece.

14. The method of claim 13, wherein the workpiece includes a substrate and a chip carried on the substrate, and, in the step of implementing the predetermined operating process to the workpiece by the operating head, the operating head performs a thermal interface material attaching process as the predetermined operating process to attach a thermal interface material to the chip of the workpiece.

15. The method of claim 13, wherein the workpiece includes a substrate and a chip carried on the substrate, and, in the step of implementing the predetermined operating process to the workpiece by the operating head, the operating head performs an adhesive bonding process as the predetermined operating process to apply an adhesive to the substrate of the workpiece.

16. The method of claim 13, wherein the workpiece includes a substrate and a chip carried on the substrate, and, in the step of implementing the predetermined operating process to the workpiece by the operating head, the operating head performs a heatsink attaching process as the predetermined operating process to attach a heatsink to the workpiece.

17. The method of claim 9, further comprising: when the electrostatic charge of the workpiece is measured to be not less than the predetermined value, eliminating the electrostatic charge of the workpiece by an electrostatic eliminator, and measuring an electrostatic charge of the workpiece by the electrostatic measuring device.

18. The method of claim 17, further comprising: when the electrostatic charge of the workpiece is measured to be not less than the predetermined value after the step of eliminating the electrostatic charge of the workpiece by the electrostatic eliminator, producing a warning alarm to an operator.

19. The method of claim 9, further comprising: after the step of implementing the predetermined operating process to the workpiece by the operating head, measuring an electrostatic charge of the workpiece by the electrostatic measuring device.
